(19) United States
(12) Patent Application Publication
(10) Pub. No.: US 2015/0060870 A1
(43) Pub. Date: Mar. 5, 2015

(54) SUPPORTING SUBSTRATE FOR MANUFACTURING FLEXIBLE INFORMATION DISPLAY DEVICE, MANUFACTURING METHOD THEREOF, AND FLEXIBLE INFORMATION DISPLAY DEVICE

(71) Applicants: Jae-Sang RO, Paju-si (KR); KEUN SOO LEE, Seoul (KR); EnSilTech Corporation, Seoul (KR)

(72) Inventors: Jae-Sang RO, Paju-si (KR); KEUN SOO LEE, Seoul (KR); YONG SEOK KIM, Seoul (KR); Won-Eui HONG, Seoul (KR); Ingoo Jang, Seoul (KR); Seung-Yeol Yang, Seoul (KR); Jin Narn JEON, Seoul (KR); Kwang Joon KIM, Seoul (KR)

(21) Appl. No.: 14/474,438

(22) Filed: Sep. 2, 2014

(30) Foreign Application Priority Data
Aug. 30, 2013 (KR) 10-2013-104536

(51) Int. Cl. H01L 27/12; B32B 38/00; B32B 37/26; B32B 37/14; B32B 37/24

(52) U.S. Cl. CPC H01L 27/1218; H01L 27/1225; H01L 27/1229; B32B 37/144; B32B 37/24; B32B 37/26; B32B 38/0008; B32B 2037/243; B32B 2037/268; B32B 2310/0881; B32B 2457/20; B32B 2310/0418
USPC 257/72; 428/141; 156/273.1; 216/34

(57) ABSTRACT

Disclosed are a supporting substrate for manufacturing a flexible information display device capable of easily separating the flexible information display device from the supporting substrate without deforming or damaging the flexible information display device, a manufacturing method thereof, and a flexible information display device manufactured thereby. The supporting substrate for manufacturing a flexible information display device includes: a coating layer formed therein with a plurality micro-protrusions formed on the supporting substrate; and a temporary bonding/debonding layer formed on the coating layer and including an adhesive material mechanically interlocked with and bonded to the supporting substrate through Van der Waals bonding force. The method provides a method capable of economically manufacturing the display device having a high resolution while reviewing a cost competitive force by reducing a device investment cost and improving the yield rate in the flexible flat panel information display device.

### CROSS-REFERENCES TO RELATED APPLICATION

This application claims priority to Korean Patent Application No. 10-2013-104536 filed on Aug. 30, 2013, the contents of which are incorporated herein by reference.

### BACKGROUND OF THE INVENTION

1. Field of the Invention

The present invention relates to a supporting substrate for manufacturing a flexible information display device, a manufacturing method thereof, and a flexible information display device. More particularly, the present invention relates to a supporting substrate for manufacturing a flexible information display device capable of easily separating the flexible information display device from the supporting substrate without deforming or damaging the flexible information display device, a manufacturing method thereof, and a flexible information display device manufactured thereby.

2. Description of the Related Art

As a current flat panel information display, a liquid crystal display (LCD), a plasma display panel (PDP), an active matrix organic light emitting display (AM OELD), and the like have been used.

Most flat panel information displays are manufactured on a surface of a glass substrate transmitting light and having excellent electric insulation characteristic. However, since the glass substrate is mechanically weak so that the glass substrate is easily damaged due to external shock or bending stress. Accordingly, the glass substrate has a difficulty in being applicable to an unbreakable or rugged information display or a flexible information display. Application of the unbreakable or flexible information display to various portable information displays such as a smart mobile phone is expected.

As examples of a flexible flat panel information display to replace an existing glass substrate, there have been many attempts to apply a thin glass sheet having a thickness of 100 μm or less representing an excellent bendable property, a flexible plastic substrate which is not damaged due to external shock, and a thin metal foil having a thickness of 100 μm or less.

However, a thin thickness and flexibility of the substrates cause the substrate to be bent or folded during various manufacturing processes such as a cleaning process, a thin film depositing process, and a patterning process to manufacture a flat panel information display so that precise alignment between masks used for the process is degraded or a deposition thickness of thin film is non-uniform.

In order to solve the problem of bending or folding of the substrate material during the process, a temporary bonding/debonding scheme is suggested. The temporary bonding/debonding scheme is a method of manufacturing a flexible information display which performs a manufacturing process of the flexible information display in a state that a flexible substrate is temporarily bonded on a glass supporting substrate by coating a flexible substrate liquid-phase material on a surface of a solid used to manufacture an existing flat panel information display, forming/laminating the flexible substrate through a curing procedure or laminating a manufactured flexible substrate to a supporting substrate by a pressing roll, and debones the flexible information display device from the glass supporting substrate when the manufacturing process of the flexible information display device is terminated.

There has been proposed a Surface Free Technology by Laser Annealing (SUFTLA) process of Sharp Corporation, Electronics on Plastic by a Laser Release (Pear) process of Philips Corporation, and a Flexible Universal Plane (Flex UP) process of Taiwan ITRI as a process of manufacturing the flexible information display by the temporary bonding/debonding scheme.

The SUFTLA process provided from Sharp Corporation is as follows. First, an a-Si layer and a SiO₂ layer are formed, and a TFT array for driving a flat panel display is manufactured at an upper portion thereof. Next, a water-soluble bonding layer is formed at an uppermost portion of the TFT array and is fixed to a first flexible substrate. A bottom surface of the a-Si layer is irradiated using XeCl laser through a lower glass supporting substrate and heated to separate the TFT array layer from the lower glass supporting substrate. In this case, the a-Si layer includes hydrogen so that hydrogen gas generated by the laser irradiation may physically delaminate the glass substrate and the TFT array layer. After the second flexible substrate is laminated and adhered to a bottom surface of the TFT array using permanent adhesive, the TFT array is separated from the first flexible substrate by solving water-soluble adhesive.

In the delamination process, thickness variation and physical/chemical characteristics of an a-Si thin film, and energy density variation of a laser beam cause non-uniformity of a delamination characteristic in a large size device. Further, a transfer process for the thin film device is performed twice which results in an increase of manufacturing process cost and a reduction in a process yield rate. In addition, a TFT layer and a capacitor constituting a pixel of a display device have a geometrical shape with different heights. This disturbs a flexible substrate and uniform bonding during a lamination procedure to damage the TFT array and to cause residual stress in the device so that a life of the device is reduced.

In the Pear process provided from Philips Corporation, a bonding layer is coated on a surface of a glass supporting substrate. After a flexible polymer substrate is bonded or formed on a surface of the bonding layer, a TFT array for driving a pixel of a flat panel display and the pixel are formed on a surface of the flexible polymer substrate. After a process of forming the TFT array and the pixel of the flat panel display is completed, a manufactured flexible information display device is separated from the glass supporting substrate by heating the bonding layer from a lower portion of the glass supporting substrate using laser. That is, the flexible information display device may be easily separated from the glass supporting substrate by selectively irradiating the laser to the bonding layer to reduce a bonding strength of the bonding layer. The invention provides various processes such as a process of heating a bonding material to a temperature in which a bonding property is degraded by an additional separation scheme, selectively melting the bonding layer dipped in a solution, or a process of simply applying a mechanical force to the bonding layer to separate the flexible information display device from the glass supporting substrate.

The Flex UP process of the ITRI uses a method of forming a bonding layer on a surface of a glass supporting substrate as in the Pear process. While the information display device is manufactured, the flexible substrate is securely fixed to the glass supporting substrate. If the manufacturing process is completed, provided is a bonding material having a characteristic which is automatically separated by a self-stress although an external debonding stress is not applied or is easily separated by applying an external small separation force because a bonding strength of the bonding layer is reduced.

In the temporary bonding/debonding method provided as a method of manufacturing the flexible information display, a process is complicated and a yield rate is low in the SUFTLA process of Sharp Corporation. A proper work condition range of a laser separation process is very sensitively influenced in the Pear process provided from Philips Corporation. An application possible temperature is low in the Flex UP process of TRI. Accordingly, in order to economically produce the flexible flat panel information display, there is a need for a new process capable of solving the above problems. As examples of the related art, disclosed is a luminescence display and a method of fabricating the same in Korean unexamined patent publication No. 10-2011-67405 and disclosed is a method of manufacturing a flexible device and a method of manufacturing a flexible display in Korean unexamined patent publication No. 10-2008-65210.

### SUMMARY OF THE INVENTION

Accordingly, the present invention has been made keeping in mind the above problems occurring when a flexible flat panel information display is manufactured using the temporary bonding/debonding process in the prior art, and an object of the present invention is to provide a supporting substrate including a temporary bonding/debonding layer capable of being easily separated without deforming the flexible information display device or damaging the device when debonding the flexible substrate on which the information display device is formed from the supporting substrate. During a manufacturing process, precision of the process is improved by minimizing the size variation of the flexible substrate so that an information display device having high resolution may be manufactured. When debonding the flexible flat panel information display device from the glass supporting substrate, deformation and damage of the device are minimized so that the information display device having high resolution may be economically manufactured.

According to an aspect of the present invention, there is provided a supporting substrate for manufacturing a flexible information display device, the supporting substrate including: a coating layer formed therein with a plurality micro-protrusions formed on the supporting substrate; and a temporary bonding/debonding layer formed on the coating layer and including an adhesive material mechanically interlocked with and bonded to the supporting substrate through Van der Waals bonding force.

According to another aspect of the present invention, there is provided a method of manufacturing a supporting substrate for manufacturing a flexible information display device, the method including: i) forming a coating layer formed therein with a plurality micro-protrusions formed on the supporting substrate; and ii) forming a temporary bonding/debonding layer bonded on the coating layer through Van der Waals bonding force using a polyelectrolyte material or an inorganic plate material representing a charge inverse to a charge of the surface of the coating layer by an electrostatic attraction.

According to another aspect of the present invention, there is provided a flexible information display device including: a flexible substrate formed therein with a plurality micro-protrusions formed on a first surface; a TFT device formed on a second surface of the flexible substrate; and a display unit formed on the TFT device.

The micro-protrusion may have a hierarchy structure forming a domain structure by optionally mixing a bar structure and a plate structure having a nano-size.

The coating layer may include one selected from the group consisting of ITO, MgO, ZnO, Al₂O₃, La₂O₃, ZrO₂, SiO₂, SnO₂, and NiO.

The micro-protrusion may have one or a combination of at least two selected from the group consisting of a regular plate shape, a regular bar shape, a regular semi-circular shape, a regular inverse semi-circular shape, a regular pyramid shape, and an irregular shape.

The micro-protrusion may have a size in the range of 1 nm to 1 μm.

The temporary bonding/debonding layer may have a thickness in the range of 0.1 nm to 1,000 nm.

The temporary bonding/debonding layer may include an inorganic plate material representing a positive charge or a negative charge in a water solution.

The temporary bonding/debonding layer may include a polyelectrolyte material representing a positive charge or a negative charge in a water solution.

The supporting substrate may further include an auxiliary layer formed on the temporary bonding/debonding layer.

The auxiliary layer may include an inorganic plate material or a polyelectrolyte material.

The inorganic plate material may include a carbon based material or a crystalline silicate.

The carbon based material may include graphene oxide.

The crystalline silicate may include one selected from the group consisting of Kaolinite, serpentine, dickite, talc, vermiculite, and montmorillonite.

The polyelectrolyte material may include one or a combination of at least two selected from the group consisting of PSS(poly(styrene sulfonate)), PEI(poly(ethylene imine)), PAA(poly(allyl amine)), PDDA(poly(diallyldimethylammonium chloride)), PNIPAM(poly(N-isopropyl acrylamide), CS(Chitosan), PMA(poly(methacrylic acid)), PVS(poly(vinyl sulfate)), PAA(poly(amic acid)), and PAH(poly(allylamine)) which are ionized in a water solution and charged with a positive charge, or may include one or a combination of at least two selected from the group consisting of NaPSS(Sodium poly(styrene sulfonate)), PVS(poly(vinly sulfonate acid)), and PCBS(Poly(1-[p-(3′-carboxy-4′-hydroxyphenylazo) benzenesulfonamido]-1,2-ethandiyl) which are ionized in a water solution and charged with a negative charge.

The inorganic plate material may include Mg-addition graphene oxide.

First, according to the manufacturing method of the present invention, an investment cost of a manufacturing device is significantly reduced. That is, since the flexible flat panel information display device is debonded from the glass supporting substrate by a mechanical scheme, there is no need for a facility having a high equipment cost and a high maintenance cost.

Secondly, according to the manufacturing process according to the present invention, since defects of the flexible flat panel information display is minimized so that the flexible flat panel information display may be debonded from the glass supporting substrate, a yield rate of the manufacturing process is improved and accordingly an economy of the manufacturing process will be reviewed.

Finally, according to the manufacturing process of the present invention, since modification of a parallel direction of the flexible substrate formed on the glass supporting substrate is minimized, a mask is easily aligned. Accordingly, a precise flexible flat panel information display having a high resolution may be manufactured.

Therefore, the material of the temporary bonding/debonding layer and the method of manufacturing the same according to the present invention may provide a method capable of economically manufacturing the display device having a high resolution while reviewing a cost competitive force by reducing a device investment cost and improving the yield rate in the flexible flat panel information display device.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a scanning electron microscope (SEM) photographic view of a micro-protrusion structure on a surface of an ITO thin film used as an example of a coating layer formed on a surface of a supporting device;

FIG. 2 is a schematic view illustrating a flexible substrate and a micro-protrusion layer which are mechanically interlocked with each other;

FIG. 3 is an SEM photographic view of a surface of a flexible substrate deboned from a surface of a glass substrate formed thereon with a micro-protrusion after the flexible substrate is optionally bonded to the surface of the glass substrate;

FIGS. 4A to 4F are schematic views illustrating surfaces having a concavo-convex shape, respectively;

FIG. 4A shows a plate shape, FIG. 4B shows a bar shape, FIG. 4C shows a semi-circular shape, FIG. 4D shows an inverse semi-circular shape, FIG. 4E shows a pyramid shape, and FIG. 4F shows an irregular shape.

FIGS. 5A and 5B are schematic views illustrating a shear bonding strength and a tensile bonding strength of a temporary bonding/debonding layer according to an embodiment of the present invention.

FIG. 6 is a schematic view illustrating a shear strain amount δ of a rectangular object achieved by applying a shear force F to the rectangular object;

FIGS. 7A to 7D are schematic views illustrating a method of forming a temporary bonding/debonding layer on a supporting substrate according to an embodiment of the present invention;

FIGS. 8A to 8F are views illustrating a process of manufacturing a flexible information display device according to an embodiment of the present invention;

FIG. 9 is an SEM photographic view of a surface of an ITO coated with graphene oxide by a process according to a first embodiment of the present invention;

FIG. 10A is a view illustrating a shape of a polyimide substrate optionally bonded to an upper portion of graphene oxide temporary bonding/debonding layer on a glass supporting substrate coated with an ITO obtained by cutting an outer peripheral portion of the polyimide substrate to have a “ [symbol] ” shape by a sharp knife;

FIG. 10B is a view illustrating an experimental result to compare a shear bonding strength when a graphene oxide layer is used as a temporary bonding/debonding layer according to a comparative example 1;

FIG. 11 is a schematic view illustrating a peel test device;

FIG. 12A is a graph illustrating a peel test result when an ITO is coated with graphene oxide as the temporary bonding/debonding layer;

FIG. 12B is a graph illustrating a peel test result when polyimide is directly coated on a surface of an ITO coating layer;

FIG. 13A is a graph illustrating a tensile bonding strength of the temporary bonding/debonding layer formed by a process according to a second embodiment of the present invention;

FIG. 13B is a graphs illustrating a peel test result when polyimide is directly coated on a surface of an ITO coating layer for comparison; and

FIG. 14 is a view illustrating an experimental result to compare a shear bonding strength when a montmorillonite layer is used as a temporary bonding/debonding layer according to a comparative example 2.

### DETAILED DESCRIPTION OF THE INVENTION

Hereinafter, an exemplary embodiment of the present invention will be described in detail with reference to the accompanying drawings. In the following description, for the illustrative purpose, the same components will be assigned with the same reference numerals, and the repetition in the description about the same components will be omitted in order to avoid redundancy. A detailed description of known functions and configurations of the present invention will be omitted when it may make the subject of the present invention unclear.

In a process of manufacturing a flexible information display device using a temporary bonding/debonding layer according to the present invention, the temporary bonding/debonding layer to bond a flexible polymer substrate to a supporting substrate should have characteristics which 1) firmly fixes the flexible substrate to the supporting substrate to minimize variation in the size of the flexible substrate under various temperature and process atmospheres and to prevent bending due to a strain, 2) prevents degradation of a bonding strength due to decomposition or degradation in a vacuum and high temperature process, and 3) easily separates the display device from the supporting substrate at a strain in which the TFT and the pixel are not damaged after the process of manufacturing the display device including a TFF process is completed.

Since a firm bonding characteristic with the glass supporting substrate being a requirement 1) is incompatible with an easy separation characteristic being a requirement in the requirements of the bonding layer, it is very difficult to provide a temporary bonding/debonding layer material having characteristics simultaneously satisfying the above requirements.

However, the inventors of the present invention invent a temporary bonding/debonding layer simultaneously satisfying incompatible requirements by suitably controlling characteristics of a thickness and a material of the temporary bonding/debonding layer through various researches, and provides a material and a manufacturing method of the temporary bonding/debonding layer based on the invented temporary bonding/debonding layer.

In general, a bonding strength of the temporary bonding/debonding layer includes two elements of a shear bonding strength and a tensile bonding strength. The shear bonding strength means a strain where a temporary bonding/debonding layer is resistant to a shear strain when the shear strain is applied to two bonded objects. A tensile bonding strength means a maximum vertical strain which the temporary bonding/debonding layer may support when the strain is vertically applied to the temporary bonding/debonding layer.

The present invention provides a method of efficiently increasing a shear bonding strength of a bonding/debonding layer 104 and a surface micro-protrusion using a mechanical interlocking mechanism by forming a coating layer 102 formed thereon with a plurality of micro-protrusions having a nano- or micro-size on the supporting substrate 100.

A coating layer 102 including a micro-protrusion according to the present invention may have a naturally irregular shape and an artificially regular shape.

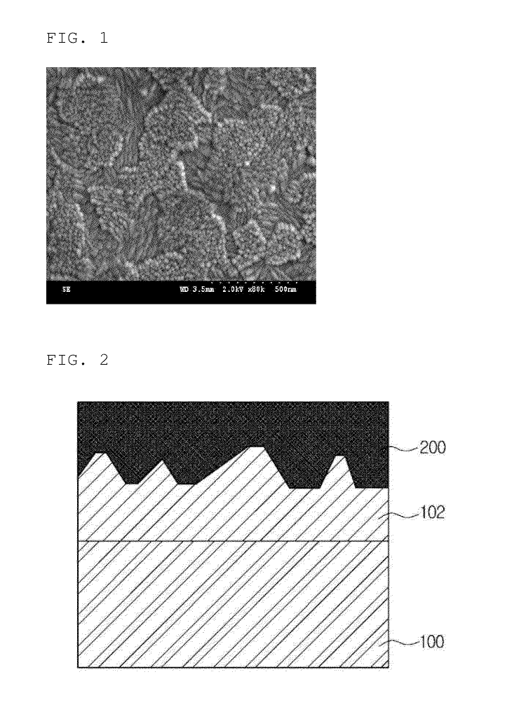

FIG. 1 is a scanning electron microscope (SEM) photographic view of a micro-protrusion structure on a surface of an ITO thin film used as an example of a coating layer formed on a surface of a supporting device.

As shown in FIG. 1, the micro-protrusion may have a hierarchy structure forming a domain structure having a size of several μm by optionally mixing a bar structure and a plate structure a size of several tens nm.

As described above, the temporary bonding/debonding layer 104 having a very thin thickness formed on the surface of the micro-protrusion causes mechanical interlocking with the micro-protrusion. This represents a result of preventing a flexible substrate formed on the supporting substrate 100 from efficiently expanding/contracting in a transverse direction.

FIG. 2 is a schematic view illustrating a flexible substrate and a micro-protrusion layer which are mechanically interlocked with each other.

Referring to FIG. 2, when the mechanical interlocking occurs, a material of the flexible substrate 200 and the temporary bonding/debonding layer 104 are boned on a plane, and are introduced and bonded between protrusions with a concavo-convex pattern. Accordingly, when the flexible substrate 200 expands or contracts, the introduced material disturbs deformation of the substrate material in a horizontal direction to efficiently limit expanding/contracting of the flexible substrate in a transverse direction. The coating layer 102 having the micro-protrusions may use an irregular micro-protrusion naturally formed during a procedure of depositing an oxide thin film such as an ITO as shown in FIG. 1. According to a research result of inventors of the present invention, the ITO protrusion structure represents a very efficient mechanical interlocking effect to significantly and efficiently limit expansion and contraction of the flexible substrate 200 in a transverse direction.

For example, the coating layer 102 including a plurality of micro-protrusions may use ITO, MgO, ZnO, Al₂O₃, La₂O₃, ZrO₂, SiO₂, SnO₂, NiO, and the like. However, the micro-protrusion according to the present invention is not limited to shapes and sizes which are naturally formed on the materials. That is, a structure of the micro-protrusion is not specially limited if a structure may efficiently represent mechanical interlocking with the flexible substrate 200 and the temporary bonding/debonding layer 104.

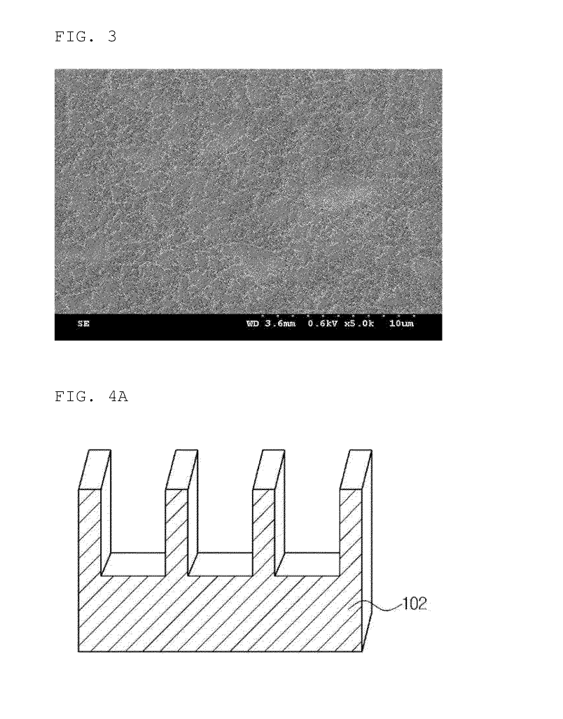

FIG. 3 is an SEM photographic view of a surface of a flexible substrate deboned from a surface of a glass substrate formed thereon with a micro-protrusion after the flexible substrate is optionally bonded to the surface of the glass substrate.

Referring to FIG. 3, after a shape of the micro-protrusion structure is optionally bonded to the surface of the glass substrate, the shape of the micro-protrusion structure is transferred to a surface of the debonded flexible substrate 200 so that an inverse shape of the protrusion structure as shown in FIG. 3 is formed on the surface of the flexible substrate 200.

Meanwhile, a protrusion of the debonded flexible substrate 200 with the micro-protrusion structure may scatter visible ray to reduce transmittance of the visible ray and to cause haze. The flexible substrate 200 requires transmittance of the visible ray is required according to a mode of the flexible information display device. Accordingly, in this case, in order to implement transmittance of the visible ray of the flexible substrate 200, the present invention provides a suitable range with respect to a size and a shape of the micro-protrusion. According to the embodiment of the present invention, it is preferable that a concavo-convex portion of the micro-protrusion structure has a height and a width in the range of 1 nm to 1 μm. It is more preferable that a concavo-convex portion of the micro-protrusion structure has a height and a width in the range of 10 nm to 100 nm.

A shape of the micro-protrusion is not specially limited if the shape may induce mechanical interlocking. For example, the micro-protrusion may have a plate shape, a bar shape, a semi-circular shape, an inverse semi-circular shape, a pyramid shape, an irregular shape, and a combination thereof.

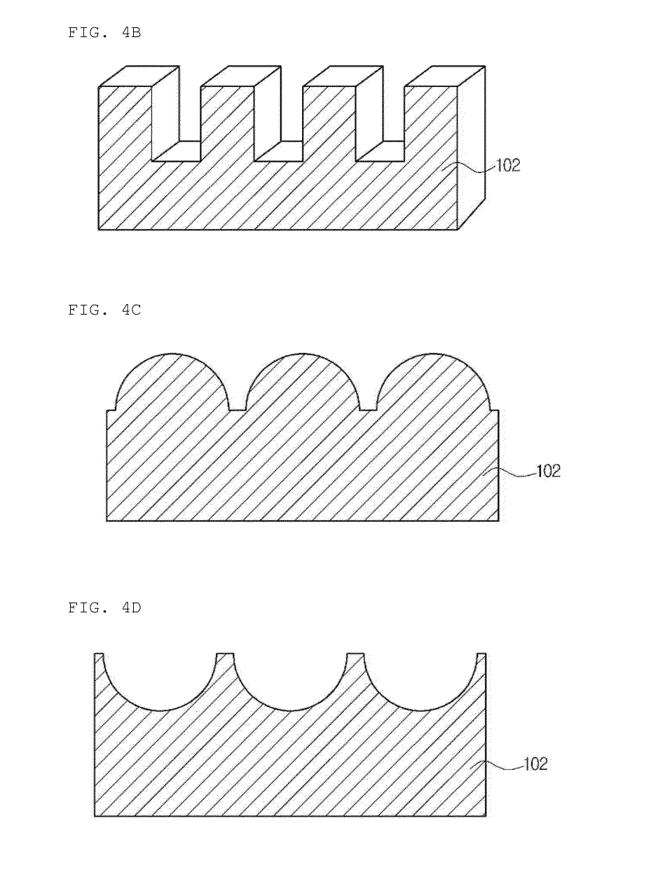

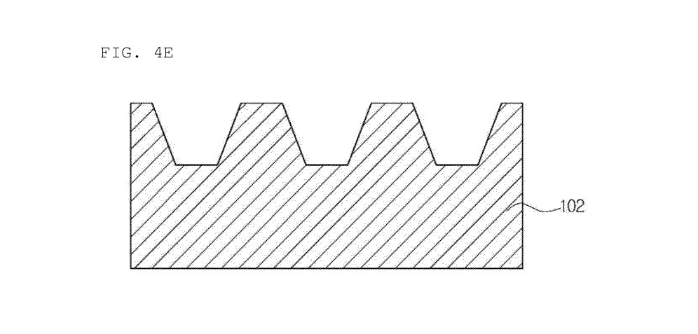

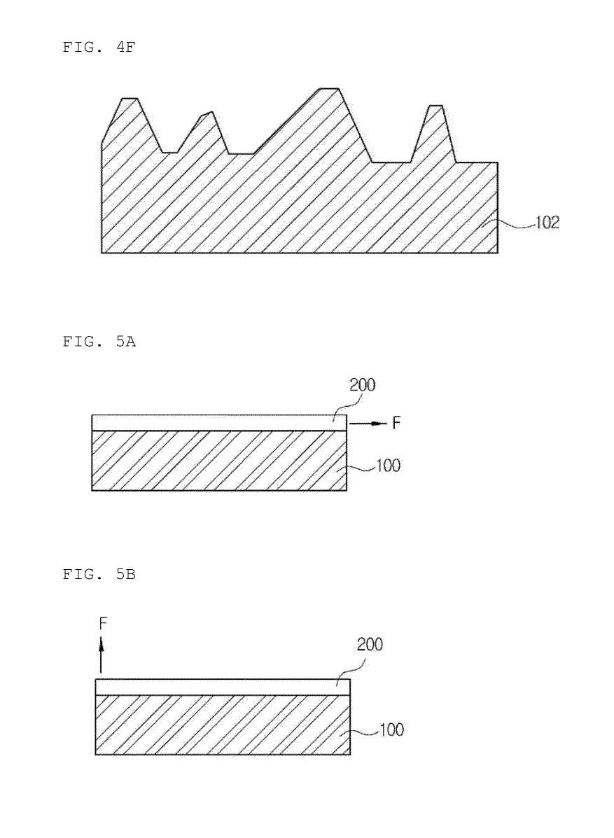

FIGS. 4A to 4F are schematic views illustrating surfaces having a concavo-convex shape, respectively. FIG. 4A shows a plate shape, FIG. 4B shows a bar shape, FIG. 4C shows a semi-circular shape, FIG. 4D shows an inverse semi-circular shape, FIG. 4E shows a pyramid shape, and FIG. 4F shows an irregular shape. The above concavo-convex shape is illustrative purpose only and a concavo-convex pattern having various shapes may be used in order to efficiently represent the mechanical interlocking. A material of a thin film is not specially limited if the material has a size and a shape of a concavo-convex surface.

The present invention may maximize a shear bonding strength between the supporting substrate 100 and the flexible substrate 200 by the micro-protrusion structure.

However, since the present invention may form a flexible device on the flexible substrate 200 to debond the flexible substrate 200 from the supporting substrate 100, the temporary bonding/debonding layer 104 capable of being bonded to the supporting substrate 100 through Van der Waals force is formed on the micro-protrusion structure to control the shear bonding strength for easy debonding of the flexible substrate 200.

Further, the supporting substrate 100 includes glass and quartz. A material of the supporting substrate 100 is not specially limited if the material is solid capable of supporting the flexible substrate during a post process.

It is preferable that the inorganic plate material includes a plate material having an aspect ratio of a thickness to a width having 100 or greater, that is, having a thickness in the range of 0.1 nm to 10 nm, and a width in the range of 0.1 μm to 1000 μm. More preferably, the inorganic material having a plate shape has a thickness in the range of 0.1 nm to 10 nm, and the width in the range of 0.1 μm to 10 μm.

The inorganic plate material includes a carbon based material having graphene and graphene oxide having a layered structure where a carbon atom is two-dimensionally arranged, and a crystalline silicate material.

Since the carbon atom is two-dimensionally arranged by sp2 bonding, the graphene and the graphene oxide have a thin plate structure, and have a thickness of about 0.3 nm. However, since the graphene has a hydrophobic property, a step of coating a large area device with the graphene is complicated, and the productivity is low, there are limitations to apply the graphene to a process requiring a process of forming a large area temporary bonding/debonding layer at a low cost. Accordingly, the present invention provides a temporary bonding/debonding layer 104 manufactured using a thin sheet composed of graphene oxide or reduced graphene oxide having a physical property and a thickness similar to those of a graphene material but having excellent dispersion property in a water solution which may be fabricated through a water solution process.

In detail, since the graphene oxide is provided therein with a base surface having epoxide ligand and hydroxyl ligand representing a hydrophilic and a lateral side to which carboxyl ligand is attached representing a negative charge in a water solution to represent an excellent dispersion property. The inventors of the present invention confirms that the temporary bonding/debonding layer 104 having a thin sheet composed of the graphene oxide has an excellent bonding strength with a suitably processed surface of the supporting substrate 100, a polymer substrate formed of a flexible substrate material, particularly, polyimide, and represents excellent productivity and economic property.

For example, the thin sheet composed of graphene oxide or reduced graphene oxide may be manufactured by oxidizing graphite with potassium permanganate (KMnO₄) and deep sulfuric acid (H₂SO₄) to obtain graphite oxide and performing intercalation and exfoliation for the graphite oxide using a Hummer process (W. S. Hummers and R. E. Offeman, J. Am. Chem. Soc., 1958, 80, 1339) and the obtained graphite oxide may be manufactured through the oxidization of the graphite and the intercalation and exfoliation of the oxidized graphite. A graphene oxide thin sheet manufactured by a certain method is not specially limited if the graphene oxide thin sheet is uniformly dispersed in a solution.

In this case, the graphene oxide thin sheet may include 1 to 10 graphene layers. Preferably, the graphene oxide thin sheet may include 1 to 5 graphene layers. More preferably, the graphene oxide thin sheet may include 1 to 2 graphene oxide layers.

Meanwhile, the graphene oxide material having a plate shape may include a little amount of Mg. When the graphene oxide material having a plate shape is used, a surface of the supporting substrate 100 represents a negative charge. When the supporting substrate 100 is a glass substrate, a surface of the glass substrate represents a negative charge. Since an inorganic plate material is not directly formed on the supporting substrate 100, as will be described later, the graphene oxide plate material includes a little amount of Mg. Accordingly, since the graphene oxide represents a positive (+) charge, the graphene oxide is easily bonded to the supporting substrate 100.

A crystalline silicate material includes a Kaolin group and a smectite group where a sheet having a Si—O tetrahedron is arranged on a plane sandwiches and is bonded to a sheet having an Al—O—OH hexahedron is arranged on a plane in a rate of 1:1 or 2:1. The Kaolin group includes Kaolinite, serpentine, and dickite, and the smectite group includes talc, vermiculite, and montmorillonite. The above materials have a structure where plate materials are laminated. Each layer has a thickness of about 1 nm, and a width in the range of 0.1 μm to 10 μm.

The materials of the smectite group generally represent a negative (−) charged on a surface in a water solution. The inventors of the present invention confirm that the temporary bonding/debonding layer 104 having the crystalline silicate thin sheet of the smectite group has an excellent bonding strength with a suitably processed surface of the supporting substrate 100, a polymer substrate formed of a flexible substrate material, particularly, polyimide, and represents excellent productivity and economic property.

Further, a material for the polyelectrolyte material is not specially limited if the material is ionized and charged with a positive charge. For example, the polyelectrolyte material may include one or a combination of at least two selected from the group consisting of PSS (poly(styrene sulfonate)), PEI(poly(ethylene imine)), PAA(poly(allyl amine)), PDDA (poly(diallyldimethylammonium chloride)), PNIPAM (poly(N-isopropyl acrylamide), CS(Chitosan), PMA(poly(methacrylic acid)), PVS(poly(vinyl sulfate)), PAA(poly(amic acid)), and PAH (poly(allylamine)). Alternatively, the polyelectrolyte material is not specially limited if the material is ionized in a water solution and charged with a negative charge. For example, the polyelectrolyte material may include one or a combination of at least two selected from the group consisting of NaPSS (Sodium poly(styrene sulfonate)), PVS (poly(vinly sulfonate acid)), and PCBS (Poly(1-[p-(3′-carboxy-4′-hydroxyphenylazo)benzenesulfonamido]-1,2-ethandiyl).

Meanwhile, in the present invention, the shear bonding strength of the temporary bonding/debonding layer 104 bonded to the supporting substrate 100 through Van der Waals force may be controlled by controlling a thickness thereof.

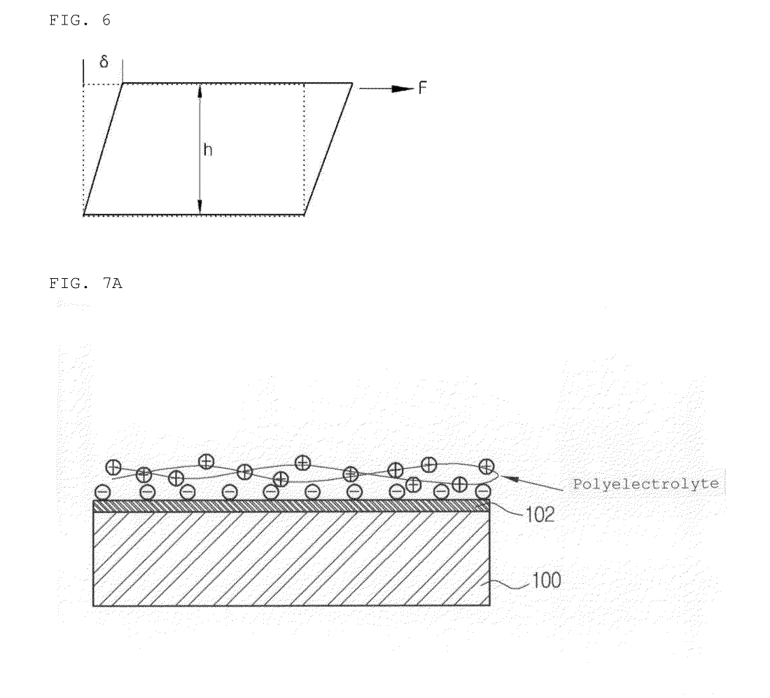

FIGS. 5A and 5B are schematic views illustrating a shear bonding strength and a tensile bonding strength of a temporary bonding/debonding layer.

Referring to FIG. 5A, a shear bonding strength of the temporary bonding/debonding layer 104 represents a capability capable of limiting a horizontal direction deformation of a flexible substrate when a glass substrate and the flexible substrate used as a supporting substrate 100 expands or contracts parallel to the temporary bonding/debonding with a different degree. Since if the shear bonding strength of the temporary bonding/debonding layer 104 is low, the size of the flexible substrate is changed or the flexible substrate is debonded from a supporting substrate so that misalignment of a mask occurs during a photolithographic process.

The shear bonding strength has the relationship expressed by a following equation with a shear modulus G of a material constituting the temporary bonding/debonding layer 104 and a thickness h of the temporary bonding/debonding layer 104. That is, as shown in FIG. 6, when the rectangular object is shear-modified by applying a shear force F to the rectangular object, a shear strength τ is obtained by a following equation.

$$τ = \frac{G δ}{h} \qquad [ Equation ]$$

Referring to the above equation, it will be understood that the shear strength τ of the temporary bonding/debonding layer 104 is increased inversely proportional to the thickness h of the temporary bonding/debonding layer 104. This is because a shear deformation rate δ/h induced based on a constant shear deformation amount δ as a thickness of the temporary bonding/debonding layer 104 is increased.

Accordingly, in order to efficiently limit the flexible substrate by increasing the shear strength of the temporary bonding/debonding layer 104, a thickness of the temporary bonding/debonding layer 104 should be reduced. For example, when the thickness of the temporary bonding/debonding layer 104 is reduced from 10 μm to 10 nm, since the shear deformation rate of the bonding layer is increased about 1,000 times with respect to the same temperature variation, it is possible to very firmly limit deformation of a material of the flexible substrate.

The shear bonding strength (see FIG. 1B) of the temporary bonding/debonding layer 104 is influenced by the shear strength and a break elongation of the bonding layer. If the shear strength and a break elongation of the temporary bonding/debonding layer 104 are increased, it is difficult to debond the flexible substrate from the supporting substrate 100.

Accordingly, the present invention suitably control the shear bonding strength of the temporary bonding/debonding layer 104 to prevent the flexible information display device from being damaged during a procedure of debonding the flexible information display device from the supporting substrate 100.

To this end, the present invention provides a method of easily debonding the flexible information display device from the supporting device 100 so that the shear bonding strength is controlled by Van der Waals bond of an interface of the supporting substrate/(temporary bonding/debonding layer)/flexible substrate.

That is, the flexible information display device is easily debonded from the supporting substrate 100 by forming the temporary bonding/debonding layer 104 by a material capable of being bonded to the supporting substrate 100 through Van der Waals force.

For this reason, according to the present invention, the size variation due to thermal expansion of the flexible substrate is efficiently limited by increasing the shear bonding strength using a very thin thickness of the supporting substrate 100 and the temporary bonding/debonding layer 104. The temporary bonding/debonding layer 104 is easily debonded by controlled the shear bonding strength by the Van der Waals bond.

To this end, according to the present invention, in order to efficiently prevent plane direction deformation of a flexible substrate by increasing the shear bonding strength of the temporary bonding/debonding layer 104, the temporary bonding/debonding layer 104 has a thickness in the range of 0.1 nm to 1000 nm.

When the thickness of the temporary bonding/debonding layer 104 is less than 0.1 nm, it is difficult to form a uniform thickness of the temporary bonding/debonding layer 104 so that it is difficult to obtain a uniform bonding/debonding strength through a large area. When the thickness of the temporary bonding/debonding layer 104 becomes greater than 1000 nm, as described in the equation, a shear bonding strength of the bonding layer is reduced so that a performance to limit deformation of the plane direction is degraded.

Preferably, the temporary bonding/debonding layer 104 according to the present invention has a thickness in the range of 0.3 nm to 100 nm. More preferably, the temporary bonding/debonding layer 104 has a thickness in the range of 0.3 nm to 10 nm. As described above, the thin temporary bonding/debonding layer 104 presents the shear bonding strength to efficiently limit plane direction deformation of the flexible substrate. Accordingly, stability and a yield rate of the TFT and a process of manufacturing a pixel may be improved.

Meanwhile, in the present invention, an auxiliary layer (not shown) may be further formed between the temporary bonding/debonding layer 104 and the supporting substrate 100 or on the temporary bonding/debonding layer 104.

The material of the auxiliary layer may use an inorganic plate material or a polyelectrolyte material representing a positive (+) charge or a negative (−) charged in a water solution.

When the temporary bonding/debonding layer 104 uses the inorganic plate material, the auxiliary layer uses the polyelectrolyte material representing a charge inverse to a charge of the inorganic material. When the temporary bonding/debonding layer 104 uses the polyelectrolyte material, the auxiliary layer uses the inorganic plate material representing a charge inverse to a charge of the polyelectrolyte material.

The reason to additionally provide the auxiliary layer is that mechanical/physical/chemical properties of the temporary bonding/debonding layer are additionally controlled using the auxiliary layer because there is a need to control the shear bonding strength and the tensile bonding strength as necessary.

The inorganic plate material and the polyelectrolyte material used as the material of the auxiliary layer uses a combination of the listed materials of the temporary bonding/debonding layer 104. The above materials may have the same thickness.

Further, according to the present invention, a layered structure of the temporary bonding/debonding layer 104 may be repeated at least twice and formed so that a total thickness does not exceed the above 1000 nm.

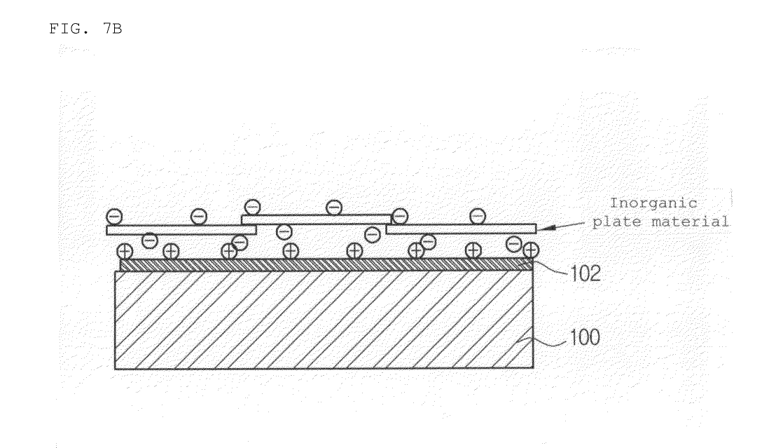

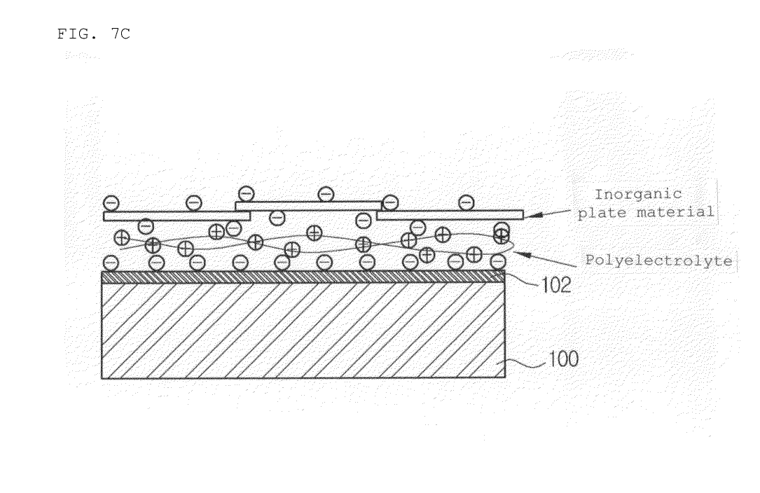

Hereinafter, a method of manufacturing a supporting substrate for manufacturing a flexible information display device will be described with reference to FIGS. 3A to 3D. FIGS. 7A to 7D are schematic views illustrating a method of forming a temporary bonding/debonding layer 104 on a supporting substrate 100 according to an embodiment of the present invention.

In detail, the method of manufacturing a supporting substrate for manufacturing a flexible information display device according to an embodiment of the present invention includes: i) forming a coating layer 102 formed therein with a plurality micro-protrusions formed on the supporting substrate 100; and ii) forming a temporary bonding/debonding layer 104 on the coating layer using a polyelectrolyte material or an inorganic plate material representing a charge inverse to a charge of the surface of the coating layer 102 by an electrostatic attraction.

Meanwhile, the method of manufacturing a supporting substrate for manufacturing a flexible information display device may further include treating a surface of the coating layer to represent a negative charge or a positive charge after step i).

The method of manufacturing a supporting substrate for manufacturing a flexible information display device may further include repeating step ii) at least once.

The coating layer 102 including the micro-protrusion may be formed on a surface of the supporting substrate 100 through various processes. First, when an oxide thin film layer such as ITO, MgO, ZnO, Al₂O₃, La₂O₃, ZrO₂, SiO₂, SnO₂, and NiO is formed, the micro-protrusion structure on the surface of the supporting substrate 100 naturally generated during a coating process is used by applying a plasma sputtering method, an electron evaporation method, a laser evaporation method, or a chemical vapor deposition method which is a general method of forming a thin film to form the thin film. In this case, it is preferable that the coating layer 102 has a thickness in the range of 10 nm to 1000 nm. More preferably, it is efficient and economical that the coating layer 102 has a thickness in the range of 10 nm to 1000 nm.

Another method of forming a surface micro-protrusion may use a transfer method by a nano-imprint process. For example, a thin coating layer 102 is formed on a surface of the supporting substrate 100 by a sol-gel process, and an inverse shape of a die is transferred by applying pressure of a die having an inverse shape of a micro-protrusion to be implemented to a surface of the coating layer. In this case, a protrusion shape of the die may include a shape artificially manufactured as schematically shown in FIGS. 4A to 4F, and may use a predetermined shape obtained by transferring a natural structure as a shape of the die. It is preferable that a high temperature thermal treatment for a micro-protrusion structure formed by a nano-imprint process is performed to present strength and chemical stability. In a case of SiO₂ sol-gel coating, it is preferable that a thermal treatment is performed at a temperature of 500° C. or higher.

Next, the temporary bonding/debonding layer 104 is formed on the coating layer 102 including the micro-protrusion using an electrostatic attraction in a water solution.

To this end, the coating layer 102 including the micro-protrusion formed on the surface of the support substrate 100 is charged by piranha solution treatment or plasma treatment.

The piranha solution is a strong oxidizer solution having a ratio of 3:1 to 7:1 of concentrated sulfuric acid (H₂SO₄) and 30% hydrogen peroxide (H₂O₂) and represents a negative charge to form a hydroxyl radical (OH) on the surface of the coating layer 102 formed on the supporting substrate 100. In the same manner, if the surface of the supporting substrate 100 is treated using O₂ plasma, formation of a hydroxyl radical (OH) is accelerated on the surface of the glass supporting substrate 100 so that the surface of the supporting substrate 100 represents a negative charge in a water solution. In contrast, if the surface of the coating layer 102 is treated using inert gas plasma such as argon plasma, an oxygen ion is selectively sputtered on the surface of the coating layer 102 and removed. Accordingly, the surface of the coating layer 102 may represent a positive charge. However, when partial oxide coating materials among materials of the coating layer 102 including a micro-protrusion on the supporting substrate 100 are dipped in the water solution without a separate processing, surfaces thereof are automatically charged. For example, when a material such as MgO, ZnO, Al₂O₃, or La₂O₃ is dipped in the water solution, a surface thereof represents a negative charge. The surface of a material in the water solution is automatically charged depending on a chemical property of the material. If the material is the coating layer 102 including the micro-protrusion on a surface of the supporting substrate, a step of treating the surface may be omitted.

FIGS. 7A to 7D are schematic views illustrating a method of forming a temporary bonding/debonding layer 104 on a coating layer 102 according to an embodiment of the present invention.

As described above, after the surface of the coating layer 102 formed on the glass supporting substrate 100 is charged, when the supporting substrate 100 is dipped in a solution in which a material representing a charge inverse to a charge of the surface of the coating layer 102, and a surface of the coating layer 102 is attracted and coated with a material representing a charge inverse to a charge of the surface of the coating layer 102 by an electrostatic attraction.

For example, if a supporting substrate charged with a negative charge by formation of a hydroxyl radical through piranha solution treatment is dipped in a PAH (poly(allylamine hydrochloride))polyelectrolyte solution charged with a positive charge in a water solution, a PAH representing the positive charge is attracted to a surface of the supporting substrate representing the negative charge by the electrostatic attraction and is coated on the surface of the supporting substrate. In this case, as the PAH is coated to shield the negative charge on the surface of the coating layer 102 on the supporting substrate 100, and covers the surface of the coating layer 102 on the supporting substrate 100 so that the surface of the supporting substrate 100 represents the positive charge (charge inversion). In this case, the coating is not performed longer by an electrostatic repulsion between the PAH on the surface of the coating layer 102 and the PAH in the solution. That is, the temporary bonding/debonding layer 104 has a self-limiting characteristic where the thickness of the temporary bonding/debonding layer 104 is not increased longer after being increased to a predetermined value. In this way, the charge inversion of the surface is schematically illustrated in FIG. 7A. In general, the temporary bonding/debonding layer 104 formed by the coating process has a thickness in the range of 0.1 nm to 10 nm. The thickness of the temporary bonding/debonding layer 104 is influenced by an ionic strength of a coating solution, and a type and a molecular weight of the polyelectrolyte material.

As described above, a phenomenon of coating one temporary bonding/debonding layer 104 on a surface of the coating layer 102 by the electrostatic attraction is schematically illustrated in FIG. 7A. As mentioned above, since the temporary bonding/debonding layer 104 is coated to a thickness to which the electrostatic attraction is applied by the electrostatic attraction, it is more preferable to form the temporary bonding/debonding layer 104 having a very thin thickness provided from the present invention. In general, the thickness of the temporary bonding/debonding layer 104 mainly depends on a surface charge and a property of the material. According to the embodiment of the present invention, it is confirmed that the temporary bonding/debonding layer 104 has a thickness in the range of 0.1 nm to 10 nm.

Meanwhile, the polyelectrolyte material is not specially limited if the material is ionized in a water solution and charged with a positive charge. For example, the polyelectrolyte material may include one or a combination of at least two selected from the group consisting of PSS(poly(styrene sulfonate)), PEI(poly(ethylene imine)), PAA(poly(allyl amine)), PDDA(poly(diallyldimethylammonium chloride)), PNIPAM(poly(N-isopropyl acrylamide), CS(Chitosan), PMA(poly(methacrylic acid)), PVS(poly(vinyl sulfate)), PAA(poly(amic acid)), and PAH(poly(allylamine)).

In the same manner, after the surface of the supporting substrate 100 is heated by argon plasma so that a positive surface charge is formed, if the supporting substrate 100 is dipped in an inorganic plate material representing the negative charge, for example, a solution in which graphene oxide is dispersed, the graphene oxide is coated on the surface of the supporting substrate 100, a coating thickness is self-limited between the coated graphene oxide and the graphene oxide in the solution by a thickness self-limiting tool to prevent the coating by the electrostatic repulsion.

In this case, the inorganic plate material includes a carbon based material or a crystalline silicate. The carbon based material includes graphene oxide, a layered silicate material such as Na-addition montmorillonite representing a negative charge, or a polyelectrolyte material charged with a positive charge in a water solution which may form the temporary bonding/debonding layer 104 in the same manner. The supporting substrate coated with the inorganic plate material representing the negative charge is schematically illustrated in FIG. 7B.

The polyelectrolyte material is not specially limited if the material is ionized in a water solution and charged with a negative charge. For example, the polyelectrolyte material may include one or a combination of at least two selected from the group consisting of NaPSS (Sodium poly(styrene sulfonate)), PVS(poly(vinly sulfonate acid)), and PCBS(Poly(1-[p-(3′-carboxy-4′-hydroxyphenylazo)benzenesulfonamido]-1,2-ethandiyl).

A single ultra-thin adhesive layer formed by the method illustrated in FIGS. 7A and 7B may be used as the temporary bonding/debonding layer 104.

Further, an auxiliary layer is formed by additionally coating a surface of the temporary bonding/debonding layer 104 with an inorganic plate material or a polyelectrolyte material representing an inverse charge so that the temporary bonding/debonding layer 104 with at least one bi-layer formed by the inorganic plate material/the polyelectrolyte material may be formed as a plurality of layers.

In another concrete example, the supporting substrate 100 having the surface coated with the PAH polyelectrolyte material representing the positive charge is dipped in a graphene oxide suspension representing the negative charge to coat graphene oxide. This is schematically illustrated in FIG. 7C. A plurality of double layers may be formed by repeatedly performing procedures shown in FIGS. 7A and 7C.

The coating method using the electrostatic attraction uses the electrostatic attraction between thin sheets including the inorganic plate material representing the negative charge and the polyelectrolyte material representing the positive charge. According to the above method, since a thin film composed of the inorganic plate material representing the negative charge by the electrostatic attraction is attracted to the surface of the supporting substrate 100 representing the positive charge by the polyelectrolyte material to form a coating layer, a ratio of a coating thickness of the inorganic plate material and the polyelectrolyte material to a coating area thereof may be controlled by adjusting a time required when the thin sheet reaches a surface of a polyelectrolyte layer.

In another concrete example, a surface of the coating layer 102 coated with graphene oxide representing a negative charge through a procedure of FIG. 7B may be again used to form a double layer using the polyelectrolyte material representing a positive charge, which is illustrated in FIG. 7B. The temporary bonding/debonding layer 104 including a plurality of double layers may be formed by repeatedly performing the procedures shown in FIGS. 7B and 7D.

In another concrete example, the double layer is applicable to Na-addition montmorillonite/polyelectrolyte material representing a positive charge. The polyelectrolyte material is not specially limited if the material is ionized in a water solution and charged with a positive charge. For example, the polyelectrolyte material may include one or a combination of at least two selected from the group consisting of PSS(poly(styrene sulfonate)), PEI(poly(ethylene imine)), PAA(poly(allyl amine)), PDDA(poly(diallyldimethylammonium chloride)), PNIPAM(poly(N-isopropyl acrylamide), CS(Chitosan), PMA(poly(methacrylic acid)), PVS(poly(vinyl sulfate)), PAA(poly(amic acid)), and PAH(poly(allylamine)).

In another concrete example, the temporary polymer bonding/debonding layer 104 by condensing and polymerizing organic monomer or oligomer material constituting polymer on the surface of the supporting substrate or the surface of the supporting substrate coated with the inorganic plate material after evaporating the organic monomer or oligomer material in a molecular state. The evaporation into the molecular state is not limited thereto. That is, various methods such as a flash evaporation may be used.

In another concrete example, the temporary polymer bonding/debonding layer 104 may be formed by printing a polymer solution on the surface of the supporting substrate 100 or the surface of the supporting substrate 100 coated with the inorganic plate material to dry the resultant object.

The method of printing the polymer solution may use spin coating, table coater method, doctor blade coating, dip coating, bar coating, screen coating, and inkjet printing, but the embodiment is not limited thereto.

In another concrete example, the temporary polymer bonding/debonding layer 104 may be formed by spray-coating a solution in which the polyelectrolyte material is melted on the surface of the supporting substrate or the surface of the supporting substrate coated with the inorganic plate material.

Through the above method, the supporting substrate for manufacturing the flexible information display device is manufactured.

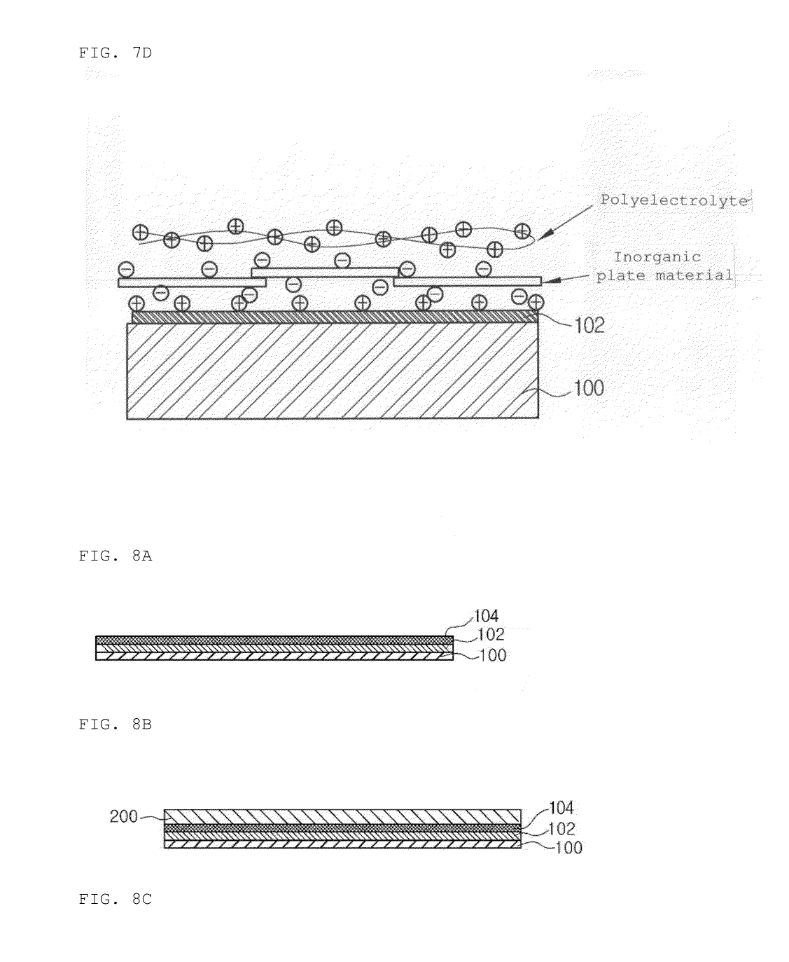

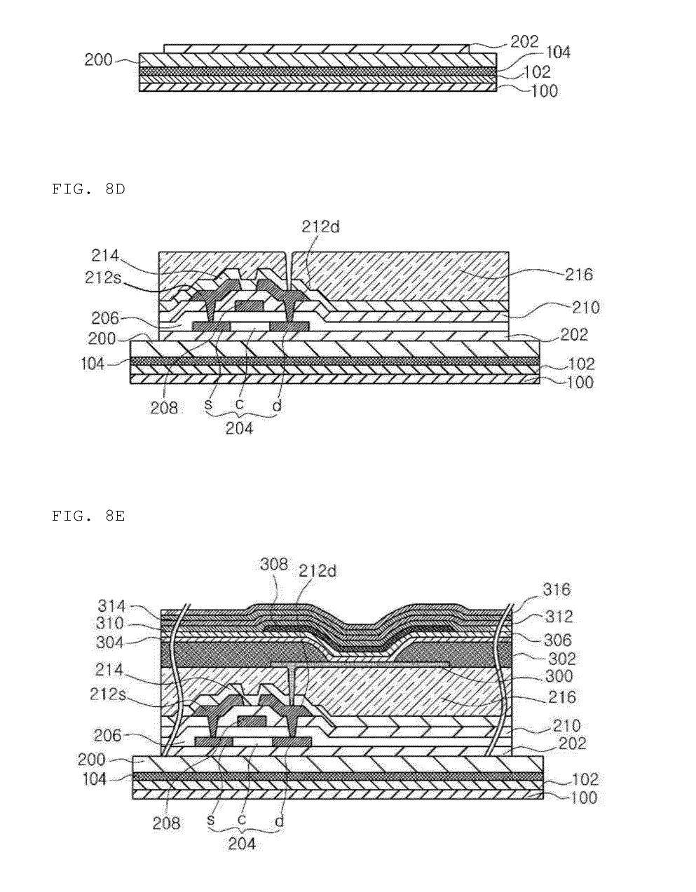

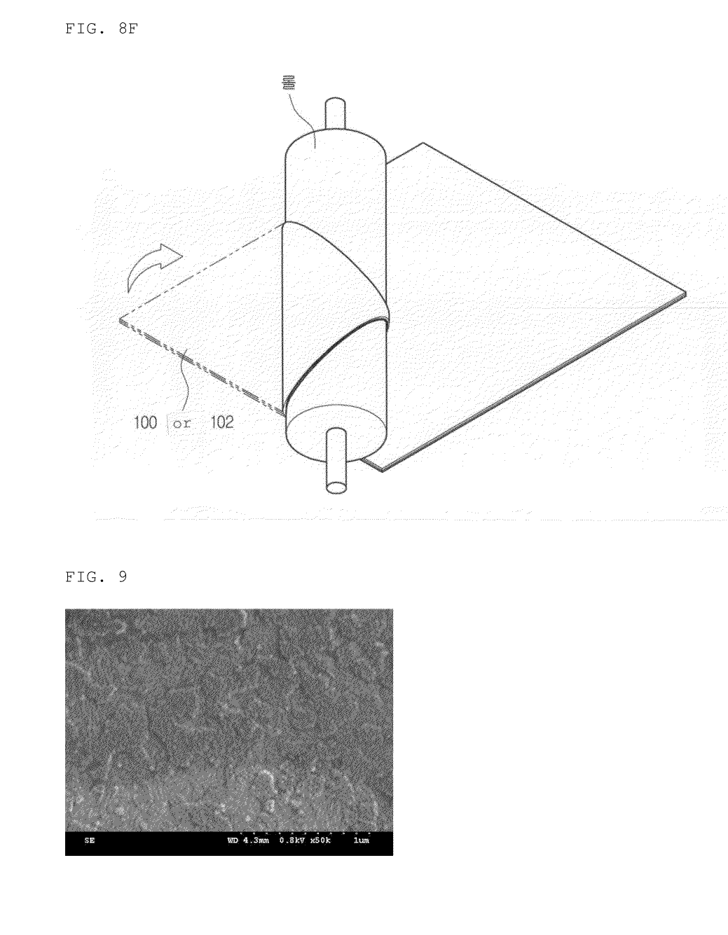

FIGS. 8A to 8F are views illustrating a process of manufacturing a flexible information display device according to an embodiment of the present invention.

Referring to FIGS. 8A and 8B, a flexible substrate 200 is formed on the supporting substrate 100 on which the temporary bonding/debonding layer 104 is formed through the above method.

The flexible substrate 200 may be formed by coating monomer, oligomer, or polymer constituting the flexible substrate 200 on a surface of the temporary bonding/debonding layer 104 to perform heat curing, UV curing, and natural dry curing therefor. The coating method of the monomer, the oligomer, or polymer may use spin coating, table coater method, doctor blade coating, and dip coating. However, the embodiment is limited thereto. That is, screen coating or inkjet printing may be used.

Further, a method of bonding the formed flexible substrate 200 on the surface of the temporary bonding/debonding layer 104 may be used using a lamination process. The method of bonding the flexible substrate 200 on the surface of the supporting substrate 100 is achieved by a lamination scheme, and the lamination of the flexible substrate 200 is achieved by applying mechanical pressure of the flexible substrate 200 to the surface of the supporting substrate 100. In another concrete example, the lamination may be achieved by applying mechanical pressure to a cylinder base.

The flexible substrate 200 serves as a flexible substrate in a final flexible device, and is not broken and has a curved surface. A TFT device and an information display device are formed on the flexible substrate 200. The thinner a thickness of the flexible substrate 200 is, the flexible substrate 200 is light and easily has a curved surface. However, when layers and devices formed on the supporting substrate 100 are separated from the flexible substrate 200, since a thickness capable of maintaining the layers and the device should be ensured by the flexible substrate 200, it is preferable that the flexible substrate 200 has a thickness in the range of 5 μm to 100 μm. More preferably, the flexible substrate 200 has a thickness in the range of 10 μm to 30 μm.

The flexible substrate 200 uses a high temperature organic layer having a property which is not changed at a high temperature. For example, the flexible substrate 200 may include acryl resin, polyethylene, polyimide, parylene, naphthalene (PEN), polyether sulfone (PES), polyethylene terephthalate (PET), polycarbonate, polyester, polyurethane, polystyrene, poly acetal, Mylar, and other plastic materials. The embodiment is not limited thereto. That is, other known flexible substrates may be used according to purposes thereof. Among them, if the polyimide has a mechanical property and is heat resistant and a device is then formed on a plastic layer, the polyimide has thermal stability so that the thermal stability is maintained during low Temperature poly silicon and activation heat treatment process.

Referring to FIG. 8C, a standard process is applicable without a separate preprocessing procedure during a next flexible device manufacturing process by forming a passivation layer 202 on the flexible substrate 200 in order to prevent moisture infiltration through the flexible substrate 200. The passivation layer 202 may use only an inorganic layer or a composite layer of the inorganic layer and a polymer layer.

The inorganic layer may include metal oxide, metal nitride, metal carbide, metal oxynitride, and a compound thereof. The metal oxide may include SiO₂, alumina, titanium, indium oxide, tin Oxide, indium tin oxide, and a compound thereof. The metal nitride may include aluminum nitride, silicon nitride, and a compound thereof. The metal carbide includes silicon carbide and the metal oxynitride may include silicon oxynitride. The inorganic layer may include silicon. A material of the inorganic layer is not specially limited if the inorganic material may block moisture and oxygen infiltration.

Meanwhile, the inorganic layer may be formed by deposition. When the inorganic layer is deposited, a pore is grown in the inorganic layer. In order to prevent the pore from being grown in the same position, a separate polymer layer may be included in addition to the inorganic layer.

The polymer layer may use organic polymer, inorganic polymer, organometallic polymer, and hybrid organic/inorganic polymer.

Referring to FIG. 4D, the passivation layer 202 is formed by a known deposition process such as a PECVD process. After the passivation layer 202 is formed, an electronic device including a thin film transistor (hereinafter referred to as ‘TFT’) is formed on the passivation layer 202. The TFT includes a poly silicon TFT, an amorphous (a)-silicon TFT, an oxide TFT, and an organic TFT.

When the TFT is used, various oxide semiconductor materials including amorphous In—Ga—Zn Oxide (a-IGZO), amorphous In—Zn Oxide (a-IZO), and amorphous In—Zn—Sn Oxide (a-IZTO) may be used. When the organic TFT is used, various organic semiconductor materials such as pentacene may be used.

When the poly silicon TFT is used, a poly silicon semiconductor layer obtained by crystallizing an amorphous silicon layer is used as a semiconductor layer, and a crystallization process such as a Rapid Thermal Annealing (RTA) process, a Solid Phase Crystallization (SPC) process, an Eximer Laser Annealing (ELA) process, a Metal Induced Crystallization (MIC) process, a Metal Induced Lateral Crystallization (MILC) process, a Super Grained Silicone (SGS) process, a Sequential Lateral Solidification (SLS) process, and a Joule Heating Crystallization (JIC) process may be performed. Since a lower substrate is formed as the flexible substrate so that a process temperature is limited, it is preferable to form the poly silicon by crystallization using a Low Temperature Polysilicone (LTPS).

In order to manufacture the poly silicon TFT, an amorphous silicon is coated on the passivation layer 202. The amorphous silicon is crystallized as a poly-silicon by one of the above crystallization methods. A semiconductor layer 204 having an island shape is formed by patterning the amorphous silicon before or after crystallization.

A gate insulation layer 206 is coated on an entire surface of a substrate. The gate insulation layer 206 may use silicon oxide, silicon nitride, or a composite layer thereof. A gate electrode material is coated on the gate insulation layer 206 and patterned to form a gate electrode 208. The gate electrode material uses a general gate electrode material. For example, the gate electrode material includes Mg, Al, Cu, Ni, Cr, Mo, W, MoW, and Au, and may have a single layer structure or a multi-layered structure by using the above elements.

After the formation of the gate electrode 208, an interlayer insulating layer 210 is formed. The interlayer insulating layer 210 may include an insulation material such as silicon oxide or silicon nitride, and an organic insulation material. After the formation of the interlayer insulating layer 210, a contact hole exposing source/drain regions s and d of the semiconductor layer 204 is formed by patterning a portion of the interlayer insulating layer 210 corresponding to the source/drain regions s and d of the semiconductor layer 204. A source/drain electrode material is coated at an upper portion of the contact hole and then patterned so that source/drain electrodes 212s and 212d are formed.

A TFT is completed by the above process. Although the present embodiment has described a top gate TFT, a gate electrode is applicable to a bottom gate TFT which is located at a bottom portion of the semiconductor layer. Although a standard process is applied, a process order or a process condition may be changed based on a technology known to those skilled in the art.

Although various electronic devices may be formed at an upper portion of the TFT, an OLED (organic light-emitting diode) will be now described for the purpose of convenience. After formation of the source/drain electrodes 212s and 212d, a passivation layer 214 and/or a planarization layer 216 are formed on the source/drain electrodes 212s and 212d.

The passivation layer 214 and the planarization layer 216 may include an organic material such as BCD or acryl resin or an inorganic material such as SiNx and silicon oxide, and may have a single layer structure or a multi-layered structure, and may be variously changed according to a process condition.

A via hole is formed by patterning the passivation layer 214 and/or the planarization layer 216 through a photolithographic process.

Referring to FIG. 8E, a first electrode 300 electrically connected to the source electrode 212s or the drain electrode 212d of the TFT is formed on the passivation layer 214 or the planarization layer 216. The first electrode 300 serves as one of electrodes included in a display device and may be used as a reflective electrode or a transmission electrode.

The transmission electrode uses ITO, IZO, ZnO or In₂O₃ as a transparent conductive oxide (TCO) or Ag, Mg, Ca, Al, Pt, Pd, Au, Ni, Nd, Ir, Cr, or a compound thereof with a thin thickness to transmit light.

The reflective electrode may be used by forming Ag, Mg, Ca, Al, Pt, Pd, Au, Ni, Nd, Ir, Cr, or a compound thereof with a thickness of a predetermined value or greater or may be used to have a multi-layered structure which forms a transparent conductive oxide layer, that is, ITO, IZO, ZnO, or In₂O₃ on the passivation layer 214 or the planarization layer 216 by using the metal layer as a reflective layer.

The first electrode 300 may serve as an anode or a cathode.

The first electrode 300 may be formed by a general layer formation process such as sputtering or vapor deposition, but the embodiment is not limited thereto.

A pixel definition layer 302 patterned with an insulation material is formed on the first electrode 300 exposing a part of the first electrode 300. The pixel definition layer 302 uses an organic insulation material such as acryl resin or polyimide or an inorganic insulation material.

After the formation of the pixel definition layer 302, first intermediate layers 304 and 306 are formed on an entire surface of the substrate. The first intermediate layers 304 and 306 include a hole injecting layer and/or a hole transporting layer or an electron injecting layer and/or an electron transporting layer. The hole injecting layer and/or the hole transporting layer and the electron injecting layer and/or the electron transporting layer are formed by a standard process and may be changed by those skilled in the art according to a process condition.

The hole injecting layer may use CuPc (copper phthalocyanine), TNATA, TCTA, TDAPB, TDATA, PANI (polyaniline) or PEDOT (poly(3,4)-ethylenedioxythiophene). The hole transporting layer may use NPD (N,N′-dinaphthyl-N,N′-diphenyl benzidine), TPD (N,N′-Bis-(3-methylphenyl)-N,N′-bis-(phenyl)-benzidine), s-TAD,MTDATA(4,4′,4″-Tris(N-3-methylphenyl-N-phenyl-amino)-triphenylamine) or PVK.

The electron transporting layer may be formed by using high molecular materials such as PBD, TAZ, and spiro-PBD or molecular materials such as Alq3, BAlq, and SAlq. The electron injecting layer may be formed by using Alq3 (tris(8-quinolinolato)aluminum), LiF (Lithium Fluoride), Ga complex, and PBD.

After that, a light emitting layer 308 is formed. The light emitting layer 308 is formed for R, G, and B, and may be formed of a phosphorescent or fluorescent material. For example, all of the R light emitting layer, the G light emitting layer, and the B light emitting layer may use the phosphorescent or fluorescent material or a combination of the phosphorescent material and the fluorescent material.

When the light emitting layer 308 is the fluorescent material, Alq3 (8-trishydroxyquinoline aluminum), distyrylarylene (DSA), DSA derivative, distyrylbenzene (DSB), DSB derivative, DPVBi (4,4′-bis(2,2′-diphenyl vinyl)-1,1′-biphenyl), DPVBi derivative, spiro-DPVBi or spiro-6P (spirosexyphenyl) may be used, but the embodiment is not limited thereto. When the light emitting layer 308 is the phosphorescent material, an arylamine based material, a carbazole based material, or a spiro based material may be used as a host material. Preferably, CBP (4,4-N,N dicarbazole-biphenyl), CBP derivative, mCP (N,N-dicarbazolyl-3,5-benzene) mCP derivative or spiro based derivative may be used as the host material. A phosphorescent organic complexed material having a central metal such as Ir, Pt, Tb, or Eu may be used as a dopant material. The phosphorescent organic complexed material may use PQIr (acac), PQ2Ir(acac), PIQIr(acac) or PtOEP, but the embodiment is not limited thereto.

The light emitting layer 308 may be used through vacuum evaporation using a fine metal mask, an inkjet printing or laser thermal transfer, but the embodiment is not limited thereto.

Second intermediate layers 310 and 312 are formed on the light emitting layer 308 through an entire surface of the substrate. The second intermediate layers 310 and 312 include a hole injecting layer and/or a hole transporting layer or an electron injecting layer and/or an electron transporting layer. When the hole injecting layer and/or the hole transporting layer are formed on the above first electrode 300 as the first intermediate layers 304 and 306, the electron injecting layer and/or the electron transporting layer are formed as the second intermediate layers 310 and 312. In the same manner, when the electron injecting layer and/or the electron transporting layer are formed as the first intermediate layers 304 and 306, the hole injecting layer and/or the hole transporting layer are formed as the second intermediate layers 310 and 312. In addition, a hole blocking layer (HBL) or an electron blocking layer (EBL) may be additionally configured. The second intermediate layer may be formed by using a material used for the first intermediate layer.

The first intermediate layers 304 and 306 and the second intermediate layers 310 and 312 are formed by a standard process and may be changed by those skilled in the art according to a process condition.

Thereafter, a second electrode 314 is formed on the second intermediate layer 312. The second electrode 314 may include a reflective electrode or a transmission electrode like the first electrode 300.

The transmission electrode uses ITO, IZO, ZnO or In₂O₃ as a transparent conductive oxide (TCO) or may form Ag, Mg, Ca, Al, Pt, Pd, Au, Ni, Nd, Ir, Cr, or a compound thereof with a thin thickness to transmit light.

The reflective electrode forms or uses Ag, Mg, Ca, Al, Pt, Pd, Au, Ni, Nd, Ir, Cr, and a compound thereof with a predetermined thickness or greater or may include a multi-layered structure which forms a transparent conductive oxide layer, that is, ITO, IZO, ZnO or In2O3 on the second intermediate layer 312.

When the first electrode 300 is an anode, the second electrode 314 is a cathode. When the first electrode 300 is the cathode, the second electrode 314 is the anode.

After the second electrode 314 is formed, a passivation layer 316 is formed on the second electrode 314 using an organic layer, an inorganic layer, and a mixed layer thereof.

After the formation of the passivation layer 316, a display device is sealed. As a sealing scheme, the display device may be sealed by a sealing substrate or using an organic layer such as parylene to surround the whole display device.

Referring to FIG. 8F, after the sealing is completed, a process of separating the flexible information display device from the supporting substrate is performed. The temporary bonding/debonding layer of the present invention represents a high shear bonding strength to efficiently limit length variation due to thermal expansion and swelling. That is, temporary bonding/debonding layers, the supporting substrate and the temporary bonding/debonding layer, or the temporary bonding/debonding layer and the flexible substrate are bonded to each other through Van der Waals bonding force. In particular, since the Van der Waals bonding force is additionally controlled using an inorganic plate material, the flexible information display device may be mechanically debonded without additional processes.

Accordingly, in the present invention, when the flexible information display device is debonded, since the temporary bonding/debonding layer 104 may be debonded from the supporting substrate 100, the temporary bonding/debonding layer 104 may remain on an entire surface or one surface of the flexible substrate 200 on which the device is not formed.

Further, according to the present invention, a shape of a surface of the coating layer having a plurality of micro-protrusions formed on the supporting substrate 100 is transferred to one surface of the flexible substrate as it is as shown in FIG. 3, a plurality of micro-protrusion structures are formed on a surface of the flexible substrate 200 on which the device is not formed.

The micro-protrusion has a hierarchy structure forming a domain structure having a micro-size by optionally mixing a bar structure and a plate structure of several tens nm.

The micro-protrusion has one or a combination of at least two selected from the group consisting of a plate shape, a bar shape, a semi-circular shape, an inverse semi-circular shape, a pyramid shape, and an irregular shape. The micro-protrusion has the size in the range of 1 nm to 1 μm. Preferably, the micro-protrusion should have the size in the range of 1 nm to 1 μm.

As described above, since the micro protrusion scatters visible ray to reduce transmittance of the visible ray, the transmittance of the visible ray is required according to a mode of the flexible information display device. Accordingly, in this case, in order to implement transmittance of the visible ray of the flexible substrate 200, the present invention requires a suitable range with respect to a size and a shape of the micro-protrusion.

According to the present invention, as schematically shown in FIG. 8F, a roll including a bonding layer is adhered on a surface of the substrate on which the flexible information display device is formed, and the temporary bonding/debonding layer is debonded from the supporting substrate by rotating the roll. In this case, it is preferable that a diameter of the roll has a size which does not excessively apply a bending stress to the flexible information display device. It is preferable that a length of one side of the supporting substrate is longer than a circumference length. Further, the roll may be used to prevent the flexible display device from being bent during debonding.

Hereinafter, embodiments of the present invention will be described. However, the embodiments of the present invention is illustrative for further understanding of the present invention only, but the present invention is not limited to following embodiments.

### Embodiment 1

A glass supporting substrate coated with an ITO is prepared. The prepared glass supporting substrate is dipped in an acetone solution and ultrasonic cleaning is performed for about 10 minutes so that foreign materials such as oil components on a surface are removed. Next, the glass supporting substrate is dipped and cleaned in an alcohol solution in the same manner and is finally cleaned in a distilled water solution in the same manner. The cleaned glass supporting substrate is dipped in a solution in which graphene oxide of 0.2 mg/ml is melted, maintains in the solution for 10 minutes to 60 minutes, and graphene oxide representing a negative charge is coated on an ITO coating surface representing a positive charge.

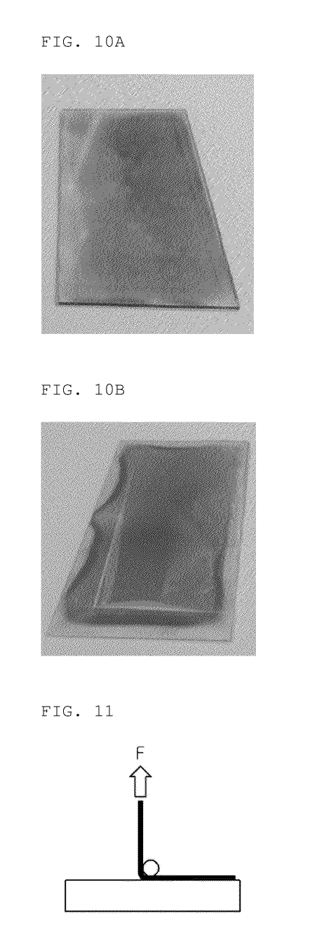

In this case, a coating solution is sprayed on the surface of the glass supporting substrate or the coating solution is repeatedly flowed on the glass supporting substrate using a shaker so that the coating solution may be sufficiently supplied to the surface of the glass supporting substrate, and the solution is stirred to have uniform concentration of the graphene oxide in the solution. Residual graphene oxide remaining on the surface of the glass supporting substrate is removed by sufficiently cleaning the glass supporting substrate coated with the graphene oxide by a distilled water, and the resulting object is heated and dried at 180° C. FIG. 9 is an SEM photographic view of an IT surface coated with graphene by a process according to a first embodiment of the present invention.

In order to coat a polyimide solution on the dried surface of the graphene oxide using a table coater, and efficiently induce imidization reaction, the dried surface of the temporary bonding/debonding layer is sequentially heated to 140° C., 240° C., 300° C., 350° C., 450° C., and is maintained for 60 minutes and is cooled at a room temperature. In this case, an increased temperature rate heated to each temperature is 5° C./min.

In order to evaluate a shear bonding strength of a prepared sample, in the present invention, the prepared sample is heated to 450° C. with an increased temperature rate of 450° C./min, maintains in this condition for 30 minutes, and is cooled at a room temperature. Next, a bonding action of a polyimide substrate is evaluated.

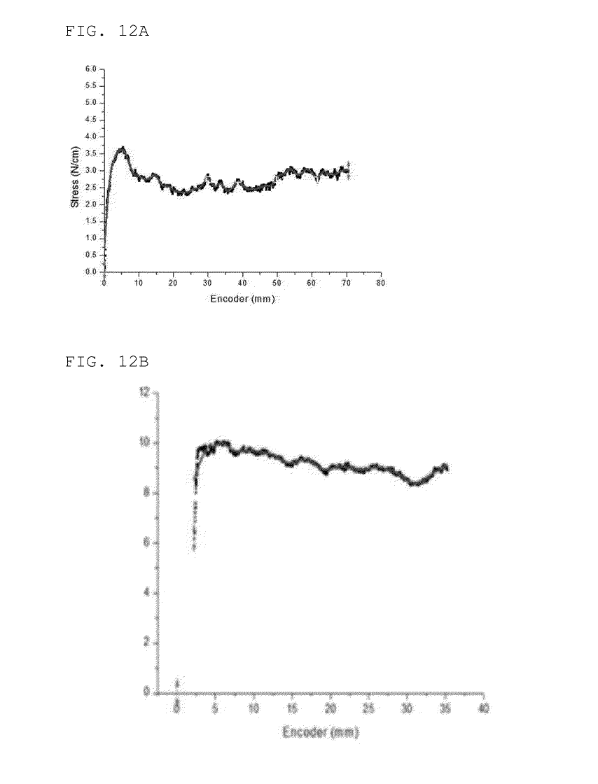

FIG. 10A is a view illustrating a shape of a polyimide substrate optionally bonded to an upper portion of graphene oxide temporary bonding/debonding layer on a glass supporting substrate coated with an ITO obtained by cutting an outer peripheral portion of the polyimide substrate to have a “ [symbol] ” shape by a sharp knife. As shown in FIG. 10A, it will be understood that the polyimide substrate is adhered to a surface of a glass supporting substrate coated with an ITO as it is. That is, mechanical interlocking efficiently fixes the polyimide substrate so that a bonding state between the polyimide substrate and the supporting substrate may maintain.

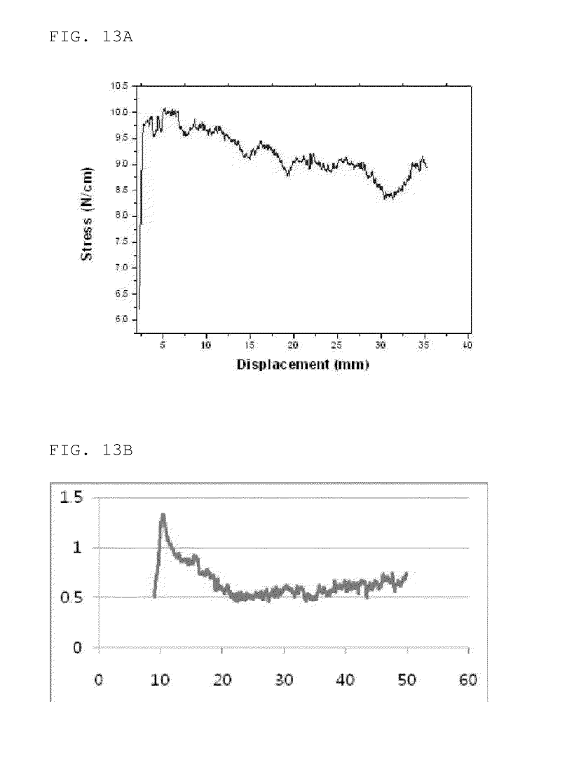

An influence of the temporary bonding/debonding layer upon the shear bonding strength is illustrated in FIGS. 12A, 12B, and 12C by measuring the shear bonding strength using a peel test device as schematically illustrated in FIG. 11.

FIG. 12A is a graph illustrating a peel test result when an ITO is coated with graphene oxide as the temporary bonding/debonding layer, and FIG. 12B is a graph illustrating a peel test result when polyimide is directly coated on a surface of an ITO coating layer. When the graphene oxide is coated on a surface of an ITO, a shear bonding strength is reduced by about ⅓ or less as compared with the ITO. That is, the graphene oxide significantly reduces the shear bonding strength of the temporary bonding/debonding layer to some extent to serve so that the manufactured flexible information display device may be easily debonded from the supporting substrate.

### Comparative Example 1

A manufacturing process of FIG. 10B is substantially equal to a manufacturing process of FIG. 10A. The difference is that FIG. 10B is an experimental result to compare a shear bonding strength when a graphene oxide layer is used on a glass supporting substrate which is not coated with an ITO as the temporary bonding/debonding layer. As shown in FIG. 10B, a cut polyimide substrate is rolled-up due to a stress in the substrate so that the temporary bonding/debonding layer does not suitably fix the polyimide substrate. That is, when there is no mechanical interlocking in a predetermined condition, a stress generated during an expansion procedure of the polyimide substrate does not suitably support the temporary bonding/debonding layer.

### Embodiment 2

A glass supporting substrate coated with an ITO is prepared. The prepared glass supporting substrate is dipped in an acetone solution and ultrasonic cleaning is performed for about 10 minutes so that foreign materials such as oil components on a surface are removed. Next, the glass supporting substrate is dipped and cleaned in an alcohol solution in the same manner and is finally cleaned in a distilled water solution in the same manner.

The cleaned glass supporting substrate is dipped in a solution in which montmorillonite of 0.2 mg/ml representing a negative charge is melted, maintains in the solution for minutes to 60 minutes, and the montmorillonite representing a negative charge is coated on an ITO coating surface representing a positive charge. In this case, a coating solution is sprayed on the surface of the glass supporting substrate or a solution is repeatedly flowed on the glass supporting substrate using a shaker so that the coating solution may be sufficiently supplied to the surface of the glass supporting substrate, and the solution is stirred to have uniform concentration of the graphene oxide in the solution. Residual montmorillonite remaining on the surface of the glass supporting substrate is removed by sufficiently cleaning the glass supporting substrate coated with the montmorillonite by a distilled water, and the resulting object is heated and dried at 180° C.

In order to coat a polyimide solution on the dried surface of the temporary bonding/debonding layer using a table coater, and efficiently induce imidization reaction, the dried surface of the temporary bonding/debonding layer is sequentially heated to 140° C., 240° C., 300° C., 350° C., 450° C., and is maintained for 60 minutes and is cooled at a room temperature. In this case, an increased temperature rate heated to each temperature is 5° C./min.

In order to evaluate a shear bonding strength of a prepared sample, in the present invention, the prepared sample is heated to 450° C. with an increased temperature rate of 450° C./min, maintains in this condition for 30 minutes, is cooled at a room temperature. Next, a bonding action of a polyimide substrate is evaluated. A shape of a polyimide substrate optionally bonded to an upper portion of montmorillonite temporary bonding/debonding layer on a glass supporting substrate coated with an ITO obtained by cutting an outer peripheral portion of the polyimide substrate to have a “ [symbol] ” shape by a sharp knife is illustrated in FIG. 10B. That is, it will be understood that the polyimide substrate adheres to the surface of the glass substrate coated with the ITO. That is, mechanical interlocking efficiently fixes the polyimide substrate so that a bonding state between the polyimide substrate and the supporting substrate may maintain.

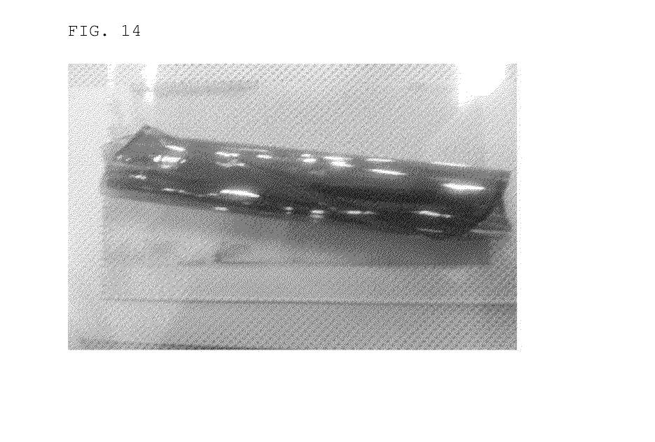

An influence of the temporary bonding/debonding layer upon the shear bonding strength is illustrated in FIGS. 12A and 12B by measuring the shear bonding strength using a peel test device as schematically illustrated in FIG. 11. FIGS. 13A and 13B illustrate the relationship between a peeling displacement and a bonding strength. When the polyimide is directly coated on a surface of an ITO coating layer for comparison, a peel test result is illustrated in FIG. 13B. When the montmorillonite is coated on a surface of an ITO, a shear bonding strength is reduced by about ⅙ or less as compared with the ITO. That is, the montmorillonite significantly reduces the shear bonding strength of the temporary bonding/debonding layer to some extent to serve so that the manufactured flexible information display device may be easily debonded from the supporting substrate.

### Comparative Example 2

A manufacturing process of FIG. 14 is substantially equal to a manufacturing process of FIG. 10B. The difference is that FIG. 14 is an experimental result to compare a shear bonding strength when a montmorillonite layer is used on a glass supporting substrate which is not coated with an ITO as the temporary bonding/debonding layer. As shown in FIG. 14, a cut polyimide substrate is rolled-up due to a stress in the substrate so that the temporary bonding/debonding layer does not suitably fix the polyimide substrate. That is, when there is no mechanical interlocking in a predetermined condition, a stress generated during an expansion procedure of the polyimide substrate does not suitably support the temporary bonding/debonding layer.

The present invention is not limited to the above-described embodiment, and may be variously modified by those skilled in the art to which the present invention pertains without departing from the spirit of the present invention and the modification falls within the scope of the present invention.

What is claimed is:

1. A supporting substrate for manufacturing a flexible information display device, the supporting substrate comprising:
a coating layer formed therein with a plurality micro-protrusions formed on the supporting substrate; and
a temporary bonding/debonding layer formed on the coating layer and comprising an adhesive material mechanically interlocked with and bonded to the supporting substrate through Van der Waals bonding force.

2. The supporting substrate of claim 1, wherein the micro-protrusion has a hierarchy structure forming a domain structure by optionally mixing a bar structure and a plate structure having a nano-size.

3. The supporting substrate of claim 1, wherein the coating layer comprises one selected from the group consisting of ITO, MgO, ZnO, Al₂O₃, La₂O₃, ZrO₂, SiO₂, SiO₂, and NiO.

4. The supporting substrate of claim 1, wherein the micro-protrusion has one or a combination of at least two selected from the group consisting of a regular plate shape, a regular bar shape, a regular semi-circular shape, a regular inverse semi-circular shape, a regular pyramid shape, and an irregular shape.

5. The supporting substrate of claim 1, wherein the temporary bonding/debonding layer comprises an inorganic plate material representing a positive charge or a negative charge in a water solution.

6. The supporting substrate of claim 1, wherein the temporary bonding/debonding layer comprises a polyelectrolyte material representing a positive charge or a negative charge in a water solution.

7. The supporting substrate of claim 1, further comprising an auxiliary layer formed on the temporary bonding/debonding layer.

8. The supporting substrate of claim 7, wherein the auxiliary layer comprises an inorganic plate material or a polyelectrolyte material.

9. The supporting substrate of claim 5 or 8, wherein the inorganic plate material comprises a carbon based material or a crystalline silicate.

10. The supporting substrate of claim 9, wherein the carbon based material comprises graphene oxide.

11. The supporting substrate of claim 10, wherein the crystalline silicate comprises one selected from the group consisting of Kaolinite, serpentine, dickite, talc, vermiculite, and montmorillonite.

12. The supporting substrate of claim 6 or 8, wherein the polyelectrolyte material comprises one or a combination of at least two selected from the group consisting of PSS(poly(styrene sulfonate)), PEI(poly(ethylene imine)), PAA(poly(allyl amine)), PDDA(poly(diallyldimethylammonium chloride)), PNIPAM(poly(N-isopropyl acrylamide), CS(Chitosan), PMA(poly(methacrylic acid)), PVS(poly(vinyl sulfate)), PAA(poly(amic acid)), and PAH(poly(allylamine)) which are ionized in a water solution and charged with a positive charge, or comprises one or a combination of at least two selected from the group consisting of NaPSS(Sodium poly(styrene sulfonate)), PVS(poly(vinly sulfonate acid)), and PCBS(Poly(1-[p-(3′-carboxy-4′-hydroxyphenylazo)benzenesulfonamido]-1,2-ethandiyl) which are ionized in a water solution and charged with a negative charge.

13. The supporting substrate of claim 5 or 8, wherein the inorganic plate material comprises Mg-addition graphene oxide.

14. A method of manufacturing a supporting substrate for manufacturing a flexible information display device, the method comprising:
i) forming a coating layer formed therein with a plurality micro-protrusions formed on the supporting substrate; and
ii) forming a temporary bonding/debonding layer bonded on the coating layer through Van der Waals bonding force using a polyelectrolyte material or an inorganic plate material representing a charge inverse to a charge of the surface of the coating layer by an electrostatic attraction.

15. The method of claim 14, further comprising treating the surface of the coating layer to represent a positive charge or a negative charge after step i).

16. The method of claim 14, further comprising repeating step ii) at least once.

17. The method of claim 15, wherein the surface treatment comprises piranha solution treatment or plasma treatment.

18. A flexible information display device comprising:
a flexible substrate formed therein with a plurality micro-protrusions formed on a first surface;
a TFT device formed on a second surface of the flexible substrate; and
a display unit formed on the TFT device.

19. The flexible information display device of claim 18, wherein the micro-protrusion has a hierarchy structure forming a domain structure by optionally mixing a bar structure and a plate structure having a nano-size.

20. The flexible information display device of claim 19, wherein the micro-protrusion has one or a combination of at least two selected from the group consisting of a regular plate shape, a regular bar shape, a regular semi-circular shape, a regular inverse semi-circular shape, a regular pyramid shape, and an irregular shape.
